(19) United States
(12) Patent Application Publication
(10) Pub. No.: US 2011/0159213 A1
(43) Pub. Date: Jun. 30, 2011

(54) CHEMICAL VAPOR DEPOSITION IMPROVEMENTS THROUGH RADICAL-COMPONENT MODIFICATION

(75) Inventors: Xiuyu Cai, Sunnyvale, CA (US); Yue Zhao, Mountain View, CA (US); Abhijit Basu Mallick, Palo Alto, CA (US); Nitin K. Ingle, San Jose, CA (US); Shankar Venkataraman, San Jose, CA (US)

(73) Assignee: Applied Materials, Inc., Santa Clara, CA (US)

(21) Appl. No.: 12/905,582

(22) Filed: Oct. 15, 2010

Related U.S. Application Data
(60) Provisional application No. 61/291,091, filed on Dec. 30, 2009.

(51) Int. Cl. C23C 16/40; C23C 16/56; C23C 16/455; C23C 16/50

(52) U.S. Cl. 427/579; 427/578

(57) ABSTRACT

A method of forming a silicon oxide layer is described. The method may include the steps of mixing a carbon-free silicon-containing precursor with a radical-nitrogen precursor, and depositing a silicon-and-nitrogen-containing layer on a substrate. The radical-nitrogen precursor is formed in a plasma by flowing ammonia and nitrogen (N₂) and/or hydrogen (H₂) into the plasma in order to allow adjustment of the nitrogen/hydrogen ratio. The silicon-and-nitrogen-containing layer may be converted to a silicon-and-oxygen-containing layer by curing and annealing the film.

### CROSS-REFERENCES TO RELATED APPLICATIONS

This application claims the benefit of U.S. Prov. Pat. App. No. 61/291,091 filed Dec. 30, 2009, and titled “FLOWABLE FILM IMPROVEMENTS THROUGH RADICAL-COMPONENT MODIFICATION,” which is entirely incorporated herein by reference for all purposes.

### BACKGROUND OF THE INVENTION

Semiconductor device geometries have dramatically decreased in size since their introduction several decades ago. Modern semiconductor fabrication equipment routinely produces devices with 45 nm, 32 nm, and 28 nm feature sizes, and new equipment is being developed and implemented to make devices with even smaller geometries. The decreasing feature sizes result in structural features on the device having decreased spatial dimensions. The widths of gaps and trenches on the device narrow to a point where the aspect ratio of gap depth to its width becomes high enough to make it challenging to fill the gap with dielectric material. The depositing dielectric material is prone to clog at the top before the gap completely fills, producing a void or seam in the middle of the gap.

Over the years, many techniques have been developed to avoid having dielectric material clog the top of a gap, or to “heal” the void or seam that has been formed. One approach has been to start with highly flowable precursor materials that may be applied in a liquid phase to a spinning substrate surface (e.g., SOG deposition techniques). These flowable precursors can flow into and fill very small substrate gaps without forming voids or weak seams. However, once these highly flowable materials are deposited, they have to be hardened into a solid dielectric material.

In many instances, the hardening process includes a heat treatment to remove carbon and hydroxyl groups from the deposited material to leave behind a solid dielectric such as silicon oxide. Unfortunately, the departing carbon and hydroxyl species often leave behind pores in the hardened dielectic that reduce the quality of the final material. In addition, the hardening dielectric also tends to shrink in volume, which can leave cracks and spaces at the interface of the dielectric and the surrounding substrate. In some instances, the volume of the hardened dielectric can decrease by 40% or more.

Thus, there is a need for new deposition processes and materials to form dielectric materials on structured substrates without generating voids, seams, or both, in substrate gaps and trenches. There is also a need for materials and methods of hardening flowable dielectric materials with fewer pores and a lower decrease in volume. This and other needs are addressed in the present application.

### BRIEF SUMMARY OF THE INVENTION

A method of forming a silicon oxide layer is described. The method may include the steps of mixing a carbon-free silicon-containing precursor with a radical-nitrogen precursor, and depositing a silicon-and-nitrogen-containing layer on a substrate. The radical-nitrogen precursor is formed in a plasma by flowing ammonia and nitrogen (N₂) and/or hydrogen (H₂) into the plasma in order to allow adjustment of the nitrogen:hydrogen ratio. The silicon-and-nitrogen-containing layer may be converted to a silicon-and-oxygen-containing layer by curing and annealing the film.

Embodiments of the invention include methods of forming a dielectric layer on a substrate in a plasma-free substrate processing region in a substrate processing chamber. The methods include flowing a nitrogen-and-hydrogen-containing gas into a plasma region to produce a radical-nitrogen precursor. The nitrogen-and-hydrogen-containing gas includes ammonia and N₂ and has a nitrogen:hydrogen atomic flow ratio into the plasma region above 1:3. The methods further include combining a carbon-free silicon-containing precursor with the radical-nitrogen precursor in the plasma-free substrate processing region and depositing the dielectric layer on the substrate.

Additional embodiments of the invention include methods of forming a dielectric layer on a substrate in a plasma-free substrate processing region in a substrate processing chamber. The methods include flowing a nitrogen-and-hydrogen-containing gas into a plasma region to produce a radical-nitrogen precursor. The nitrogen-and-hydrogen-containing gas includes ammonia and hydrogen (H₂) and has a nitrogen:hydrogen atomic flow ratio into the plasma region below 1:3. The methods further include combining a carbon-free silicon-containing precursor with the radical-nitrogen precursor in the plasma-free substrate processing region and depositing the dielectric layer on the substrate.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a flowchart illustrating selected steps for making a silicon oxide film according to embodiments of the invention.

FIG. 2 is a graph of the dependence of film shrinkage on supplementary N₂ flow rate.

FIG. 3 is another flowchart illustrating selected steps for forming a silicon oxide film in a substrate gap according to embodiments of the invention.

FIG. 4 shows a substrate processing system according to embodiments of the invention.

FIG. 5A shows a substrate processing chamber according to embodiments of the invention.

FIG. 5B shows a showerhead of a substrate processing chamber according to embodiments of the invention.

### DETAILED DESCRIPTION OF THE INVENTION

A method of forming a silicon oxide layer is described. The method may include the steps of mixing a carbon-free silicon-containing precursor with a radical-nitrogen precursor, and depositing a silicon-and-nitrogen-containing layer on a substrate. The radical-nitrogen precursor is formed in a plasma by flowing ammonia and nitrogen (N₂) and/or hydrogen (H₂) into the plasma in order to allow adjustment of the nitrogen:hydrogen ratio. The silicon-and-nitrogen-containing layer may be converted to a silicon-and-oxygen-containing layer by curing and annealing the film.

Increasing the concentration of nitrogen used to form the radical-nitrogen precursor reduces nascent flowability but generally produces a higher film quality (e.g. higher density, less shrinkage). On the other hand, increasing the concentration of hydrogen used to form the radical-nitrogen precursor increases the nascent flowability during deposition at the expense of film quality. Following the deposition, the silicon-and-nitrogen-containing layer may be cured and/or annealed in oxygen-containing environments to convert the layer to silicon oxide.

Additional details about the methods and systems of forming the silicon oxide layer will now be described.

### Exemplary Silicon Oxide Formation Process

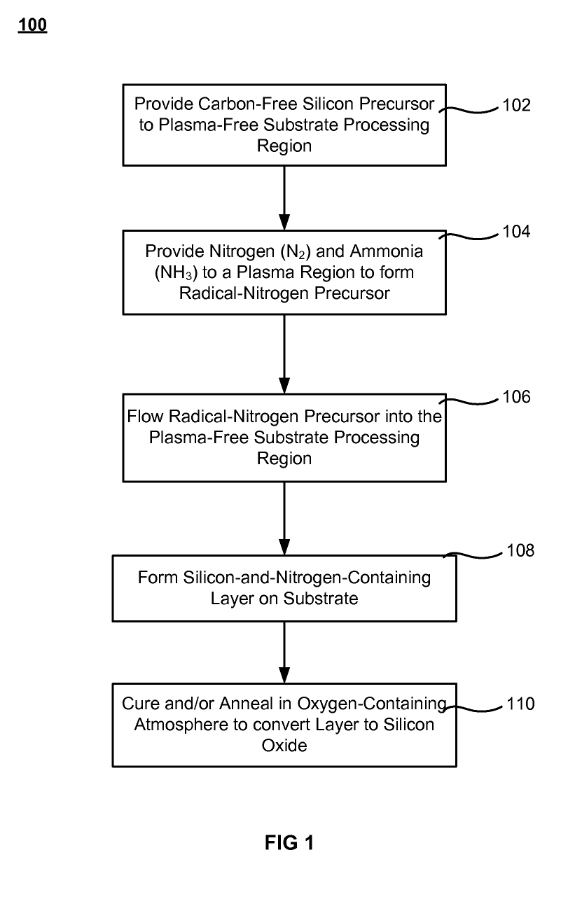

FIG. 1 is a flowchart showing selected steps in methods 100 of making silicon oxide films according to embodiments of the invention. The method 100 includes providing a carbon-free silicon-containing precursor to a substrate processing region 102. The carbon-free silicon-containing precursor may be, for example, a silicon-and-nitrogen precursor, a silicon-and-hydrogen precursor, or a silicon-nitrogen-and-hydrogen-containing precursor, among other classes of silicon precursors. The silicon-precursor may be oxygen-free in addition to carbon-free. The lack of oxygen results in a lower concentration of silanol (Si—OH) groups in the silicon-and-nitrogen layer formed from the precursors. Excess silanol moieties in the deposited film can cause increased porosity and shrinkage during post deposition steps that remove the hydroxyl (—OH) moieties from the deposited layer.

Specific examples of carbon-free silicon-containing precursors may include silyl-amines such as H₂N(SiH₃), HN(SiH₃)₂, and N(SiH₃)₃, among other silyl-amines. The flow rates of a silyl-amine may be greater than or about 200 sccm, greater than or about 300 sccm or greater than or about 500 sccm in different embodiments. All flow rates given herein refer to a dual chamber substrate processing system. Single wafer systems would require half these flow rates and other wafer sizes would require flow rates scaled by the processed area. These silyl-amines may be mixed with additional gases that may act as carrier gases, reactive gases, or both. Examples of the these additional gases may include H₂, N₂, NH₃, He, and Ar, among other gases. Examples of carbon-free silicon-containing precursors may also include silane (SiH₄) either alone or mixed with other silicon (e.g., N(SiH₃)₃), hydrogen (e.g., H₂), and/or nitrogen (e.g., N₂, NH₃) containing gases. Carbon-free silicon-containing precursors may also include disilane, trisilane, even higher-order silanes, and chlorinated silanes, alone or in combination with one another or the previously mentioned carbon-free silicon-containing precursors. The carbon-free silicon-containing precursor is not excited in a plasma region (e.g. a remote plasma region) before entering the plasma-free substrate processing region.

Nitrogen (N₂) and ammonia (NH₃) are delivered to a plasma region to form a radical-nitrogen precursor 104. The radical-nitrogen precursor is a nitrogen-radical-containing precursor generated in the plasma region outside the substrate processing region from the nitrogen and ammonia. For example, the stable nitrogen precursor compound containing NH₃ and N₂ may be activated in a chamber plasma region or a remote plasma system (RPS) outside the processing chamber to form the radical-nitrogen precursor, which is then transported into the substrate processing region 106. The flow rate of the ammonia may be greater than or about 300 sccm, greater than or about 500 sccm or greater than or about 700 sccm in different embodiments while the flow rate of the nitrogen (N₂) may be greater than or about 150 sccm, greater than or about 250 sccm or greater than or about 400 sccm in different embodiments. The radical-nitrogen precursor produced in the chamber plasma region may be one or more of .N, .NH, .NH₂, etc., and may also be accompanied by ionized species formed in the plasma. The radical-nitrogen precursor flows into the plasma-free substrate processing region 106.

In embodiments employing a chamber plasma region, the radical-nitrogen precursor is generated in a section of the substrate processing region partitioned from a deposition region where the precursors mix and react to deposit the silicon-and-nitrogen layer on a deposition substrate (e.g., a semiconductor wafer). The radical-nitrogen precursor may also be accompanied by a carrier gas such as helium, argon etc. The substrate processing region may be described herein as “plasma-free” during the growth of the silicon-and-nitrogen-containing layer and during the low temperature ozone cure. “Plasma-free” does not necessarily mean the region is devoid of plasma. Ionized species created within the plasma region do travel through pores (apertures) in the partition (showerhead) but the carbon-free silicon-containing precursor is not substantially excited by the plasma power applied to the plasma region. The borders of the plasma in the chamber plasma region are hard to define and may encroach upon the substrate processing region through the apertures in the showerhead. In the case of an inductively-coupled plasma, a small amount of ionization may be effected within the substrate processing region directly. Furthermore, a low intensity plasma may be created in the substrate processing region without eliminating the flowable nature of the forming film. All causes for a plasma having much lower intensity ion density than the chamber plasma region during the creation of the radical nitrogen precursor do not deviate from the scope of “plasma-free” as used herein.

In the substrate processing region, the carbon-free silicon-containing precursor and the radical-nitrogen precursor mix and react to form a silicon-and-nitrogen-containing film on the deposition substrate 108. The deposited silicon-and-nitrogen-containing film may deposit conformally with certain recipe combinations (e.g. by maintaining low pressure in the substrate processing region or by adding oxygen, by a variety of means, to the plasma). In other embodiments, the deposited silicon-and-nitrogen-containing film is flowable unlike conventionally deposited silicon nitride (Si₃N₄) films. The flowable nature during deposition allows the film to flow into narrow gaps trenches and other structures on the deposition surface of the substrate.

Nascent flowability may be due to a variety of properties which result from mixing a radical-nitrogen precursors with carbon-free silicon-containing precursor. These properties may include a significant hydrogen component in the deposited film and/or the presence of short chained polysilazane polymers. These short chains grow and network to form more dense dielectric material during and after the formation of the film. For example the deposited film may have a silazane-type, Si—NH—Si backbone (i.e., a Si—N—H film). When both the silicon-containing precursor and the radical-nitrogen precursor are carbon-free, the deposited silicon-and-nitrogen-containing film is also substantially carbon-free. Of course, “carbon-free” does not necessarily mean the film lacks even trace amounts of carbon. Carbon contaminants may be present in the precursor materials that find their way into the deposited silicon-and-nitrogen precursor. The amount of these carbon impurities however are much less than would be found in a silicon-containing precursor having a carbon moiety (e.g., TEOS, TMDSO, etc.).

Following the deposition of the silicon-and-nitrogen-containing layer, the deposition substrate may be cured and/or annealed in oxygen-containing atmosphere(s) 110. The curing may occur in an ozone-containing atmosphere at a substrate temperature below or about 400° C. Under some conditions (e.g. between substrate temperatures from about 100° C. to about 200° C.) the conversion has been found to be substantially complete so a relatively high temperature anneal in an oxygen-containing environment may be unnecessary in embodiments. Following curing of the silicon-and-nitrogen containing layer, it may be desirable to anneal the substrate in an oxygen-containing atmosphere to further convert the film to silicon oxide. The oxygen-containing atmosphere may include one or more oxygen-containing gases such as molecular oxygen (O₂), ozone (O₃), water vapor (H₂O), hydrogen peroxide (H₂O₂) and nitrogen-oxides (NO, NO₂, etc.), among other oxygen-containing gases. The oxygen-containing atmosphere may also include radical oxygen and hydroxyl species such as atomic oxygen (O), hydroxides (OH), etc., that may be generated remotely and transported into the substrate chamber. Ions of oxygen-containing species may also be present. The oxygen anneal temperature of the substrate may be between about 500° C. and about 1100° C. When plasma is used, it may be in the substrate processing region, in a separate region separated by a showerhead or in a remote plasma system (RPS).

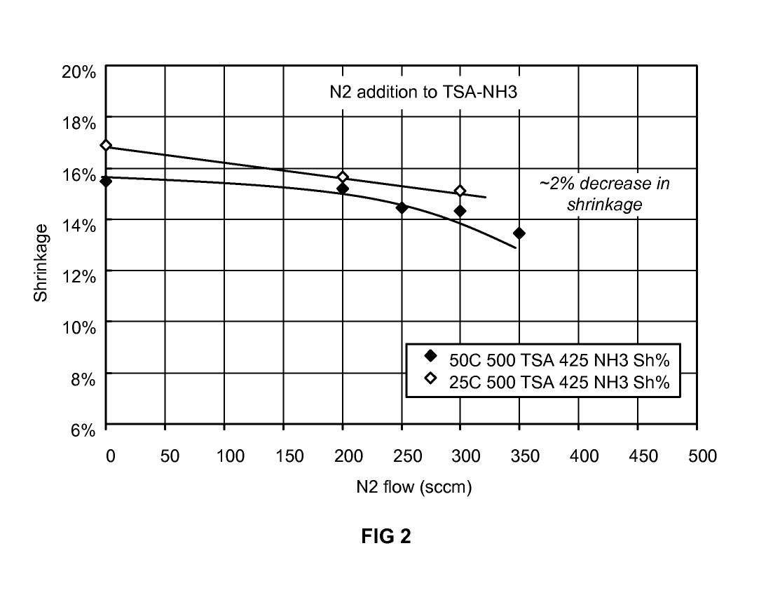

The oxygen-containing atmospheres of both the curing and oxygen anneal provide oxygen to convert the silicon-and-nitrogen-containing film into the silicon oxide (SiO₂) film. As noted previously, the lack of carbon in the silicon-and-nitrogen-containing film results in significantly fewer pores formed in the final silicon oxide film. It also results in less volume reduction (i.e., shrinkage) of the film during the conversion to the silicon oxide. For example, where a silicon-nitrogen-carbon layer formed from carbon-containing silicon precursors and radical-nitrogen may shrink by 40 vol. % or more when converted to silicon oxide, the substantially carbon-free silicon-and-nitrogen films may shrink by about 17 vol. % or less. FIG. 2 is a graph of the dependence of film shrinkage when nitrogen is combined with ammonia in the plasma region. Selecting a larger nitrogen:hydrogen atomic flow ratio by choosing a relatively large flow of nitrogen into the plasma region typically further reduces the shrinkage. Shrinkage may be below or about 17 vol. %, below or about 16 vol. %, below or about 15 vol. % or below or about 14 vol. % in different embodiments. The nitrogen:hydrogen atomic flow ratio may be above 1:3 (1/3), above or about 1:2, above or about 2:3 or above or about 1:1 in different embodiments. Herein, a ratio of n₂:m₂ is said to be above (or below) a ratio n₁:d₁ if n₂/d₂ is above (or below) n₁/d₁.

Generally speaking, the stable nitrogen precursors in each of the examples described herein are nitrogen-and-hydrogen-containing gases which include nitrogen (N₂) and/or hydrogen (H₂) combined with ammonia. As such, hydrogen (H₂) may also be added to the plasma region in combination with ammonia to increase the flowability of the carbon-free silicon-and-nitrogen films formed in the plasma-free substrate processing region. Nitrogen (N₂) may or may not be concurrently flowed to the plasma region since hydrogen and nitrogen have roughly counteracting effects. The nitrogen:hydrogen atomic flow ratio for a flow of a nitrogen-and-hydrogen-containing gas may be below 1:3, below or about 1:4, below or about 1:5 or below or about 1:7 in different embodiments. Film shrinkage, which roughly decreased for increasing nitrogen flow, will typically increase for increased hydrogen delivered to the plasma region.

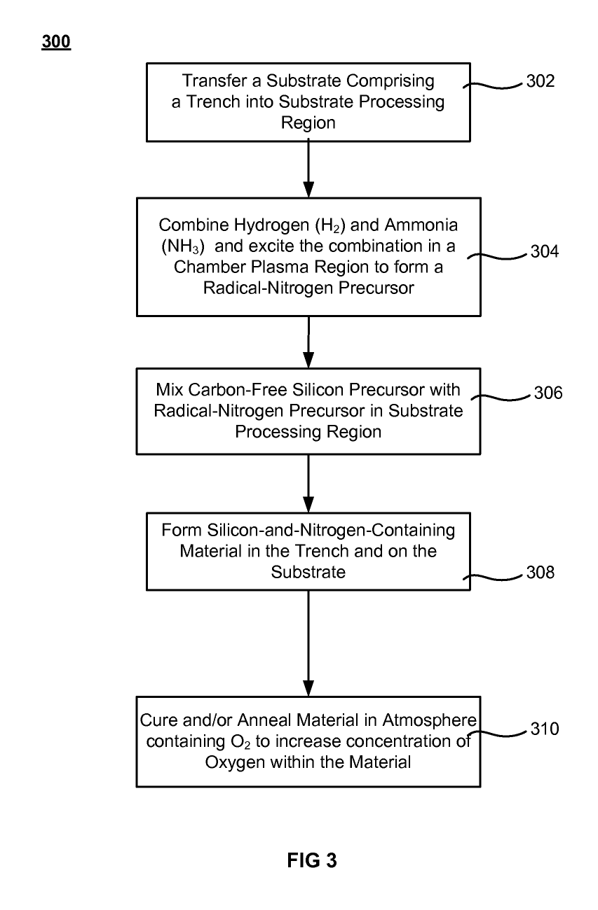

Referring now to FIG. 3, another flowchart is shown illustrating selected steps in methods 300 for forming a silicon oxide film in a substrate gap according to embodiments of the invention. The method 300 includes transferring a substrate comprising a gap into a substrate processing region (operation 302). The substrate has gaps for the spacing and structure of device components (e.g., transistors) formed on the substrate. The gaps may have a height and width that define an aspect ratio (AR) of the height to the width (i.e., H/W) that is significantly greater than 1:1 (e.g., 5:1 or more, 6:1 or more, 7:1 or more, 8:1 or more, 9:1 or more, 10:1 or more, 11:1 or more, 12:1 or more, etc.). In many instances the high AR is due to small gap widths of that range from about 90 nm to about 22 nm or less (e.g., about 90 nm or less, 65 nm or less, 45 nm or less, 32 nm or less, 28 nm or less, 22 nm or less, 16 nm or less, etc.).

Hydrogen (H₂) is combined with Ammonia (NH₃) to form a nitrogen-and-hydrogen-containing gas. The nitrogen-and-hydrogen-containing gas is excited in a chamber plasma region to form a radical-nitrogen precursor 304. The combination may be formed in the chamber plasma region or before the combination enters the region. Either way, the plasma creates the radical-nitrogen precursor which flows through apertures in a showerhead separating the plasma region from the substrate processing region. A carbon-free silicon-containing precursor is mixed with the radical nitrogen precursor in the substrate processing region (operation 306). A flowable silicon-and-nitrogen-containing layer is deposited on the substrate (operation 308). Because the layer is flowable, it can fill the gaps having the high aspect ratios without creating voids or weak seams around the center of the filling material. For example, a depositing flowable material is less likely to prematurely clog the top of a gap before it is completely filled to leave a void in the middle of the gap.

The as-deposited silicon-and-nitrogen-containing layer may then be cured in an ozone-containing atmosphere and/or annealed in an oxygen-containing atmosphere (operation 210) to transition the silicon-and-nitrogen-containing layer to silicon oxide. A further anneal (not shown) may be carried out in an inert environment at a higher substrate temperature in order to densify the silicon oxide layer. Curing and annealing the as-deposited silicon-and-nitrogen-containing layer in an oxygen-containing atmosphere forms a silicon oxide layer on the substrate, including the substrate gap 208. In embodiments, the processing parameters of operations 208 and 210 possess the same ranges described with reference to FIG. 1. As noted above, the silicon oxide layer has fewer pores and less volume reduction than similar layers formed with carbon-containing precursors that have significant quantities of carbon present in the layer before the heat treatment step. In many cases, the volume reduction is slight enough (e.g., about 15 vol. % or less) to avoid post heat treatment steps to fill, heal, or otherwise eliminate spaces that form in the gap as a result of the shrinking silicon oxide.

The silicon-and-nitrogen-containing and silicon oxide layers referred to herein may be part of a processing sequence. The silicon-and-nitrogen-containing layer may transition into a silicon oxide layer via a curing and/or annealing in the oxygen-containing atmospheres described. The term “dielectric layer” may be used herein to describe either a silicon-and-nitrogen-containing-layer or a silicon oxide layer or any intermediate layer, for that matter. Depending on the application, the intermediate layer may be sufficient for a given purpose and a complete transition to silicon oxide may be unnecessary. As such, “dielectric layer” encompasses all these possibilities. Additional details regarding processing which form dielectric layers are presented in the course of describing an exemplary dielectric deposition system.

### Exemplary Dielectric Deposition System

Deposition chambers that may implement embodiments of the present invention may include high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers. Specific examples of CVD systems that may implement embodiments of the invention include the CENTURA ULTIMA® HDP-CVD chambers/systems, and PRODUCER® PECVD chambers/systems, available from Applied Materials, Inc. of Santa Clara, Calif.

Examples of substrate processing chambers that can be used with exemplary methods of the invention may include those shown and described in co-assigned U.S. Provisional Patent App. No. 60/803,499 to Lubomirsky et al, filed May 30, 2006, and titled “PROCESS CHAMBER FOR DIELECTRIC GAPFILL,” the entire contents of which is herein incorporated by reference for all purposes. Additional exemplary systems may include those shown and described in U.S. Pat. Nos. 6,387,207 and 6,830,624, which are also incorporated herein by reference for all purposes.

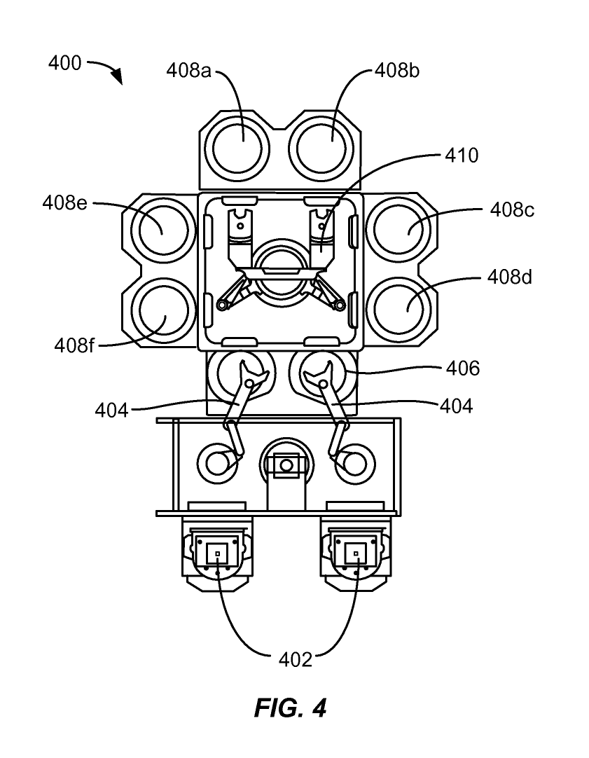

Embodiments of the deposition systems may be incorporated into larger fabrication systems for producing integrated circuit chips. FIG. 4 shows one such system 400 of deposition, baking and curing chambers according to disclosed embodiments. In the figure, a pair of FOUPs (front opening unified pods) 402 supply substrate substrates (e.g., 300 mm diameter wafers) that are received by robotic arms 404 and placed into a low pressure holding area 406 before being placed into one of the wafer processing chambers 408a-f. A second robotic arm 410 may be used to transport the substrate wafers from the holding area 406 to the processing chambers 408a-f and back.

The processing chambers 408a-f may include one or more system components for depositing, annealing, curing and/or etching a flowable dielectric film on the substrate wafer. In one configuration, two pairs of the processing chamber (e.g., 408c-d and 408e-f) may be used to deposit the flowable dielectric material on the substrate, and the third pair of processing chambers (e.g., 408a-b) may be used to anneal the deposited dielectic. In another configuration, the same two pairs of processing chambers (e.g., 408c-d and 408e-f) may be configured to both deposit and anneal a flowable dielectric film on the substrate, while the third pair of chambers (e.g., 408a-b) may be used for UV or E-beam curing of the deposited film. In still another configuration, all three pairs of chambers (e.g., 408a-f) may be configured to deposit and cure a flowable dielectric film on the substrate. In yet another configuration, two pairs of processing chambers (e.g., 408c-d and 408e-f) may be used for both deposition and UV or E-beam curing of the flowable dielectric, while a third pair of processing chambers (e.g. 408a-b) may be used for annealing the dielectric film. Any one or more of the processes described may be carried out on chamber(s) separated from the fabrication system shown in different embodiments.

In addition, one or more of the process chambers 408a-f may be configured as a wet treatment chamber. These process chambers include heating the flowable dielectric film in an atmosphere that include moisture. Thus, embodiments of system 400 may include wet treatment chambers 408a-b and anneal processing chambers 408c-d to perform both wet and dry anneals on the deposited dielectric film.

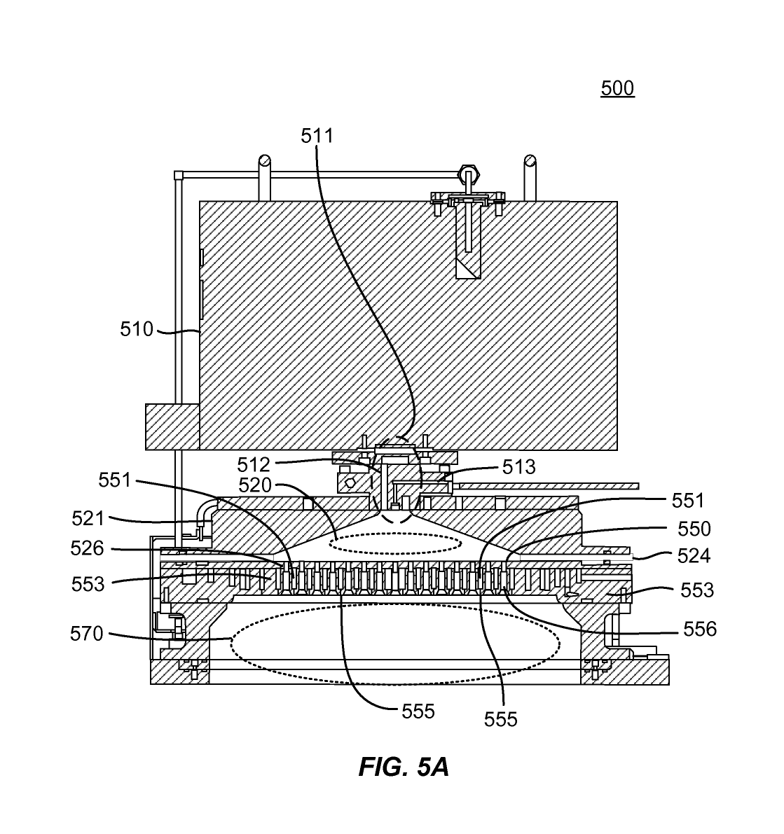

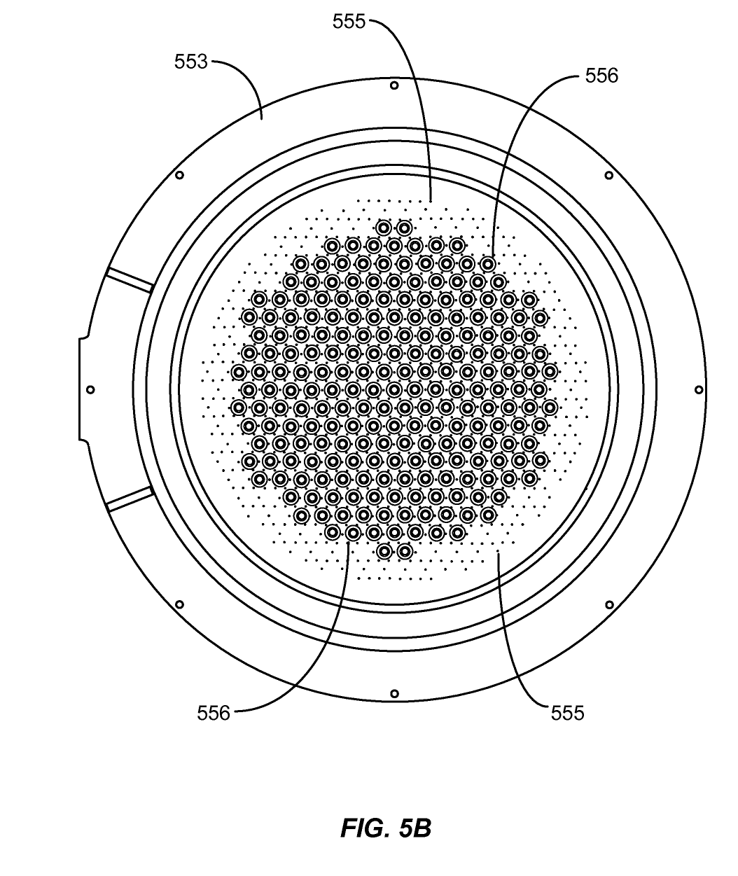

FIG. 5A is a substrate processing chamber 500 according to disclosed embodiments. A remote plasma system (RPS) 510 may process a gas which then travels through a gas inlet assembly 511. Two distinct gas supply channels are visible within the gas inlet assembly 511. A first channel 512 carries a gas that passes through the remote plasma system RPS 510, while a second channel 513 bypasses the RPS 500. The first channel 502 may be used for the process gas and the second channel 513 may be used for a treatment gas in disclosed embodiments. The lid (or conductive top portion) 521 and a perforated partition 553 are shown with an insulating ring 524 in between, which allows an AC potential to be applied to the lid 521 relative to perforated partition 553. The process gas travels through first channel 512 into chamber plasma region 520 and may be excited by a plasma in chamber plasma region 520 alone or in combination with RPS 510. The combination of chamber plasma region 520 and/or RPS 510 may be referred to as a remote plasma system herein. The perforated partition (also referred to as a showerhead) 553 separates chamber plasma region 520 from a substrate processing region 570 beneath showerhead 553. Showerhead 553 allows a plasma present in chamber plasma region 520 to avoid directly exciting gases in substrate processing region 570, while still allowing excited species to travel from chamber plasma region 520 into substrate processing region 570.

Showerhead 553 is positioned between chamber plasma region 520 and substrate processing region 570 and allows plasma effluents (excited derivatives of precursors or other gases) created within chamber plasma region 520 to pass through a plurality of through holes 556 that traverse the thickness of the plate. The showerhead 553 also has one or more hollow volumes 551 which can be filled with a precursor in the form of a vapor or gas (such as a silicon-containing precursor) and pass through small holes 555 into substrate processing region 570 but not directly into chamber plasma region 520. Showerhead 553 is thicker than the length of the smallest diameter 550 of the through-holes 556 in this disclosed embodiment. In order to maintain a significant concentration of excited species penetrating from chamber plasma region 520 to substrate processing region 570, the length 526 of the smallest diameter 550 of the through-holes may be restricted by forming larger diameter portions of through-holes 556 part way through the showerhead 553. The length of the smallest diameter 550 of the through-holes 556 may be the same order of magnitude as the smallest diameter of the through-holes 556 or less in disclosed embodiments.

In the embodiment shown, showerhead 553 may distribute (via through holes 556) process gases which contain oxygen, hydrogen and/or nitrogen and/or plasma effluents of such process gases upon excitation by a plasma in chamber plasma region 520. In embodiments, process gases excited in RPS 510 and/or chamber plasma region 520 include ammonia (NH₃) and nitrogen (N₂) and/or hydrogen (H₂) with relative flowrates to result in a predetermined nitrogen:hydrogen atomic flow ratio. Generally speaking, the process gas introduced into the RPS 510 and/or chamber plasma region 520 through first channel 512 may contain one or more of oxygen (O₂), ozone (O₃), N₂O, NO, NO₂, NH₃, NₓH_{y} including N₂H₄, silane, disilane, TSA and DSA. The process gas may also include a carrier gas such as helium, argon, nitrogen (N₂), etc. The second channel 513 may also deliver a process gas and/or a carrier gas, and/or a film-curing gas used to remove an unwanted component from the growing or as-deposited film. Plasma effluents may include ionized or neutral derivatives of the process gas and may also be referred to herein as a radical-oxygen precursor and/or a radical-nitrogen precursor referring to the atomic constituents of the process gas introduced.

In embodiments, the number of through-holes 556 may be between about 60 and about 2000. Through-holes 556 may have a variety of shapes but are most easily made round. The smallest diameter 550 of through holes 556 may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 555 used to introduce a gas into substrate processing region 570 may be between about 100 and about 5000 or between about 500 and about 2000 in different embodiments. The diameter of the small holes 555 may be between about 0.1 mm and about 2 mm.

FIG. 5B is a bottom view of a showerhead 553 for use with a processing chamber according to disclosed embodiments. Showerhead 553 corresponds with the showerhead shown in FIG. 5A. Through-holes 556 are depicted with a larger inner-diameter (ID) on the bottom of showerhead 553 and a smaller ID at the top. Small holes 555 are distributed substantially evenly over the surface of the showerhead, even amongst the through-holes 556 which helps to provide more even mixing than other embodiments described herein.

An exemplary film is created on a substrate supported by a pedestal (not shown) within substrate processing region 570 when plasma effluents arriving through through-holes 556 in showerhead 553 combine with a silicon-containing precursor arriving through the small holes 555 originating from hollow volumes 551. Though substrate processing region 570 may be equipped to support a plasma for other processes such as curing, no plasma is present during the growth of the exemplary film.

A plasma may be ignited either in chamber plasma region 520 above showerhead 553 or substrate processing region 570 below showerhead 553. A plasma is present in chamber plasma region 520 to produce the radical nitrogen precursor from an inflow of a nitrogen-and-hydrogen-containing gas. An AC voltage typically in the radio frequency (RF) range is applied between the conductive top portion 521 of the processing chamber and showerhead 553 to ignite a plasma in chamber plasma region 520 during deposition. An RF power supply generates a high RF frequency of 13.56 MHz but may also generate other frequencies alone or in combination with the 13.56 MHz frequency.

The top plasma may be left at low or no power when the bottom plasma in the substrate processing region 570 is turned on to either cure a film or clean the interior surfaces bordering substrate processing region 570. A plasma in substrate processing region 570 is ignited by applying an AC voltage between showerhead 553 and the pedestal or bottom of the chamber. A cleaning gas may be introduced into substrate processing region 570 while the plasma is present.

The pedestal may have a heat exchange channel through which a heat exchange fluid flows to control the temperature of the substrate. This configuration allows the substrate temperature to be cooled or heated to maintain relatively low temperatures (from room temperature through about 120° C.). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded heater element configured to make two full turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The substrate processing system is controlled by a system controller. In an exemplary embodiment, the system controller includes a hard disk drive, a floppy disk drive and a processor. The processor contains a single-board computer (SBC), analog and digital input/output boards, interface boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

The system controller controls all of the activities of the CVD machine. The system controller executes system control software, which is a computer program stored in a computer-readable medium. Preferably, the medium is a hard disk drive, but the medium may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to instruct the system controller.

A process for depositing a film stack on a substrate or a process for cleaning a chamber can be implemented using a computer program product that is executed by the system controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. A layer of “silicon oxide” may include minority concentrations of other elemental constituents such as nitrogen, hydrogen, carbon and the like. In some embodiments of the invention, silicon oxide consists essentially of silicon and oxygen. A gas in an “excited state” describes a gas wherein at least some of the gas molecules are in vibrationally-excited, dissociated and/or ionized states. A gas (or precursor) may be a combination of two or more gases (precursors). The term “trench” is used throughout with no implication that the etched geometry has a large horizontal aspect ratio. Viewed from above the surface, trenches may appear circular, oval, polygonal, rectangular, or a variety of other shapes. The term “via” is used to refer to a low aspect ratio trench which may or may not be filled with metal to form a vertical electrical connection. The term “precursor” is used to refer to any process gas (or vaporized liquid droplet) which takes part in a reaction to either remove or deposit material from a surface.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursor and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of forming a dielectric layer on a substrate in a plasma-free substrate processing region in a substrate processing chamber, the method comprising:
flowing a nitrogen-and-hydrogen-containing gas into a plasma region to produce a radical-nitrogen precursor, wherein the nitrogen-and-hydrogen-containing gas comprises ammonia and N₂ and has a nitrogen:hydrogen atomic flow ratio into the plasma region above 1:3;
combining a carbon-free silicon-containing precursor with the radical-nitrogen precursor in the plasma-free substrate processing region; and
depositing the dielectric layer on the substrate.

2. The method of claim 1 wherein the nitrogen-and-hydrogen-containing gas further comprises hydrogen (H₂).

3. The method of claim 1 wherein the nitrogen:hydrogen atomic flow ratio is greater than or about 1:2.

4. The method of claim 1 wherein the carbon-free silicon-containing precursor comprises a silicon-and-nitrogen-containing precursor.

5. The method of claim 1 wherein the carbon-free silicon-containing precursor comprises N(SiH₃)₃.

6. The method of claim 1 wherein the dielectric layer comprises a carbon-free Si—N—H layer.

7. The method of claim 1 further comprising an operation of curing the dielectric layer by maintaining a temperature of the substrate at a curing temperature less than or about 400° C. in an ozone-containing atmosphere.

8. The method of claim 1 further comprising raising a temperature of the substrate to an oxygen anneal temperature above or about 600° C. in an oxygen-containing atmosphere comprising one or more gases selected from the group consisting of atomic oxygen, ozone, and steam (H₂O).

9. The method of claim 1 wherein the plasma region is in a remote plasma system.

10. The method of claim 1, wherein the plasma region is a partitioned portion of the substrate processing chamber separated from the plasma-free substrate processing region by a showerhead.

11. A method of forming a dielectric layer on a substrate in a plasma-free substrate processing region in a substrate processing chamber, the method comprising:
flowing a nitrogen-and-hydrogen-containing gas into a plasma region to produce a radical-nitrogen precursor, wherein the nitrogen-and-hydrogen-containing gas comprises ammonia and hydrogen (H₂) and has a nitrogen:hydrogen atomic flow ratio into the plasma region below 1:3;
combining a carbon-free silicon-containing precursor with the radical-nitrogen precursor in the plasma-free substrate processing region; and
depositing the dielectric layer on the substrate.

12. The method of claim 11 wherein the nitrogen-and-hydrogen-containing gas further comprises nitrogen (N₂).

13. The method of claim 11 wherein the nitrogen:hydrogen atomic flow ratio is less than or about 1:4.

14. The method of claim 11 wherein the carbon-free silicon-containing precursor comprises a silicon-and-nitrogen-containing precursor.

15. The method of claim 11 wherein the carbon-free silicon-containing precursor comprises N(SiH₃)₃.

16. The method of claim 11 wherein the dielectric layer comprises a carbon-free Si—N—H layer.

17. The method of claim 11 further comprising an operation of curing the dielectric layer by raising a temperature of the substrate to a curing temperature less than or about 400° C. in an ozone-containing atmosphere.

18. The method of claim 11 further comprising an operation of annealing the substrate by raising a temperature of the substrate to an oxygen anneal temperature above or about 600° C. in an oxygen-containing atmosphere comprising one or more gases selected from the group consisting of atomic oxygen, ozone, and steam (H₂O).

19. The method of claim 11 wherein the plasma region is in a remote plasma system.

20. The method of claim 11 wherein the plasma region is a partitioned portion of the substrate processing chamber separated from the plasma-free substrate processing region by a showerhead.
